(19) United States
(12) Patent Application Publication
(10) Pub. No.: US 2004/0060899 A1
(43) Pub. Date: Apr. 1, 2004

(54) Apparatuses and methods for treating a silicon film

(75) Inventors: Ann Waldhauer, La Honda, CA (US); Paul B. Comita, Menlo Park, CA (US)

Correspondence Address: PATENT COUNSEL, APPLIED MATERIALS, INC., Legal Affairs Department, P.O. BOX 450A, Santa Clara, CA, 95052, US

(73) Assignee: Applied Materials, Inc.

(21) Appl. No.: 10/263,098

(22) Filed: Oct. 1, 2002

(51) Int. Cl. C23F 1/00; C23C 16/00

(52) U.S. Cl. 216/2

(57) ABSTRACT

A method of treating a silicon film on a substrate. A silicon film is provided. The silicon film is thinned using a gas cluster ion beam (GCIB) process. The silicon film surface then is smoothed out using an etching process or an annealing process. Optionally, an encapsulation film is formed on the silicon film after the GCIB process and the etching process or the annealing process.

### BACKGROUND OF THE INVENTION

1. Field of the Invention

The present invention relates to treating a silicon film and more specifically to methods and apparatuses for thinning and smoothing a silicon film.

2. Discussion of Related Art

During the past several years, demand for silicon on insulator (SOI) substrates has greatly increased. Devices such as transistors and capacitors typically formed on a silicon wafer can be formed on the SOI substrates. SOI substrates are in high demand because they have low current leakage, which allows electronic devices created on the SOI substrates to consume less power. Additionally, the electronic devices created on the SOI substrates can be made smaller.

An SOI substrate can be created using several processes. For example, an SOI substrate may be fabricated using a separation by implant oxygen (SIMOX) process, of bond and etch back (BE) process, a hydrogen implant and release silicon process (sometimes known as SmartCut®) (“SmartCut®” is a registered trademark of Soitec Silicon on insulator technology S.A.), or by using a plasma implanting oxygen into silicon process. All of these methods are well practiced in the arts. Most of the methods of fabricating SOI substrates have some common disadvantages, non-uniform thickness and non-smooth surface. The SOI substrates thus exhibit higher surface roughness than bulk or epitaxial silicon wafers. Conventional methods to treat the surfaces of the SOI wafers include plasma polishing, chemical mechanical polishing, gas cluster ion beam (GCIB) processing, annealing processing, and hydrochloric acid etching processing.

Conventional methods have several disadvantages. Plasma polishing introduces non-uniformity and some surface damages associated with plasma polishing to the SOI substrate surfaces. It is difficult to obtain a thin SOI substrate with chemical mechanical polishing. GCIB process gives good thickness control but a film processed under a GCIB process does not have a very smooth surface. Annealing and hydrochloric acid etching processes give good smoothness control but do not etch a film efficiently. For example, an annealing process typically only smoothes a surface. A hydrochloric acid etching process may etch and smooth a film but does not have good thickness control. None of these methods can produce thin SOI substrates that have uniform thickness and smooth surfaces.

It is desirable to be able to fabricate a thin silicon film with a controlled uniform thickness profile and a smooth surface.

### SUMMARY OF THE INVENTION

The present invention relates to methods and apparatuses for treating a silicon film. In one aspect of the invention, to treat the silicon film, a combination of a gas cluster ion beam (GCIB) etching process and a smoothing process is used. The GCIB etching process is used to thin the film to a thickness. The smoothing process is used to smooth the silicon film. The smoothing process can be an annealing process or an H₂:HCl etching process.

In another aspect of the invention, the initial non-uniformity on the silicon film surface is mapped to obtain an initial non-uniformity mapping information. Next, a gas cluster ion beam (GCIB) is directed towards the silicon film surface. The GCIB is modulated as the GCIB is being directed at the silicon film surface in accordance to the initial non-uniformity mapping information to thin the silicon film to a thickness. The silicon film surface is then smoothed using an annealing process such as a rapid thermal annealing. Optionally, an encapsulation film is formed over the silicon film that is thinned and smoothed by soaking the silicon film with an ozone gas.

In another aspect of the invention, the initial non-uniformity on the silicon film surface is mapped to obtain an initial non-uniformity mapping information. Next, an intended non-uniformity mapping information is created which is used to incorporate an intended non-uniformity profile into the silicon film surface. Then, a gas cluster ion beam (GCIB) is directed towards the silicon film surface. The GCIB is modulated as the GCIB is being directed at the silicon film surface in accordance to the initial non-uniformity mapping information and the intended non-uniformity mapping information to thin the silicon film to a thickness and to incorporate the intended non-uniformity profile into the silicon film surface as the silicon film is being thinned. The silicon film surface is then smoothed using a smoothing process that has smoothing profile that compensates for the intended non-uniformity to smooth out the intended non-uniformity profile such as an H₂:HCl etching process. Optionally, an encapsulation film is formed over the silicon film that is thinned and smoothed by soaking the silicon film with an ozone gas.

### BRIEF DESCRIPTION OF THE DRAWINGS

The present invention is illustrated by way of example and not limitation in the figures of the accompanying drawings, in which like references indicate similar elements and in which:

FIG. 1A illustrates an exemplary method of using a GCIB and an H₂:HCl etching processes to treat the silicon film;

FIG. 1B illustrates another exemplary method of using a GCIB and an H₂:HCl etching processes to treat the silicon film;

FIG. 1C illustrates an exemplary method of using a GCIB and an annealing processes to treat the silicon film;

FIG. 1D illustrates another exemplary method of using a GCIB and an annealing processes to treat the silicon film;

FIG. 2A illustrates an exemplary method of thinning the silicon film and incorporating an intended non-uniformity profile using a GCIB process;

FIG. 2B illustrates an exemplary method of smoothing the silicon film surface;

FIG. 2C illustrates an exemplary method of thinning the silicon film with a GCIB process and then annealing the silicon film;

FIG. 3 illustrates an exemplary gas cluster ion beam (GCIB) processing apparatus which can be utilized to thin a silicon film in accordance with the present invention;

FIG. 4 illustrates an exemplary apparatus which can be utilized to smooth a silicon film in accordance with the present invention;

FIG. 5A illustrates an exemplary cluster tool which can be used for some exemplary embodiments of the present invention;

FIG. 5B illustrates an exemplary loadlock apparatus which can be utilized to form an encapsulation film;

FIGS. 6A-6K illustrate an exemplary process of making an SOI substrate in accordance with the present invention; and

FIG. 7 illustrates an exemplary contour map that indicates an initial non-uniformity profile of a silicon film.

### DETAILED DESCRIPTION OF THE PRESENT INVENTION

The present invention describes methods and apparatuses for treating a silicon film, which is useful for fabricating a silicon-on-insulator (SOI) substrate. In the following description numerous specific details are set forth in order to provide a through understanding of the present invention. One skilled in the art will appreciate that these specific details are not necessary in order to practice the present invention. In other instances, well known equipment features and processes have not been set forth in detail in order to not unnecessarily obscure the present invention.

The exemplary embodiments of the present invention include methods and apparatuses for treating a silicon film. Treating the silicon film includes first thinning the silicon film to a thickness and then smoothing the silicon film surface. Optionally, the silicon film is protected with an encapsulation layer after being thinned and smoothed. A silicon film that can be treated using the exemplary embodiments of the present invention includes a silicon film in an SOI substrate or silicon films on other type of well-known substrates.

Throughout the following discussion, the term “silicon film” generally refers to a silicon film, a silicon alloy film, or any other silicon containing film (e.g., silicon germanium film). The silicon film may be of any crystalline form such as an amorphous, polycrystalline and monocrystalline. The silicon film may be formed on or be part of any well known substrate such as an oxide film, an SOI substrate, etc. The term “silicon film surface” generally refers to a surface of such silicon film described above. Additionally, the term “H₂:HCl etching process” refers to an etching process that uses a gas mixture that comprises a hydrochloric acid and a hydrogen (H₂) gases.

In one embodiment, a silicon film is provided. The silicon film is thinned using a gas cluster ion beam (GCIB) etching process. The silicon film is then smoothed using a smoothing process. Examples of a smoothing process that can be used include an H₂:HCl etching process and an annealing process.

In another embodiment, a silicon film is provided. The silicon film is thinned and at the same time, an intended non-uniformity profile is incorporated into the silicon film. The silicon film is then smoothed using a smoothing process. An example of a process that can incorporate the intended non-uniformity profile is a GCIB etching process. And, examples of a smoothing process that can be used include an H₂:HCl etching process and an annealing process. The reason for incorporating the intended non-uniformity profile and then smooth out the intended non-uniformity profile will be apparent from the discussion below.

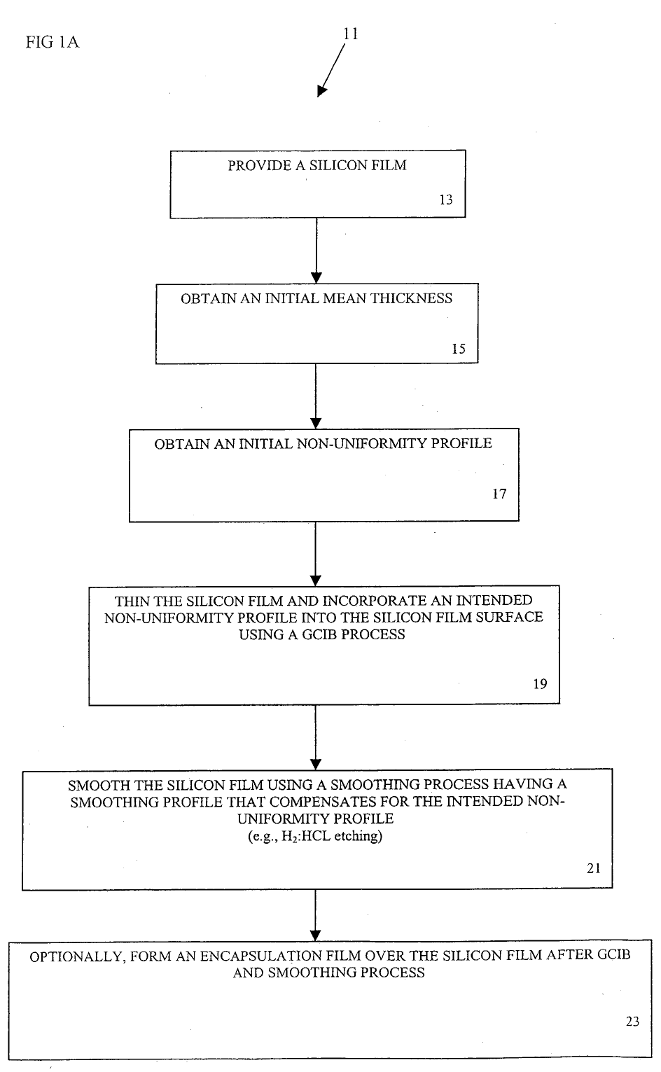

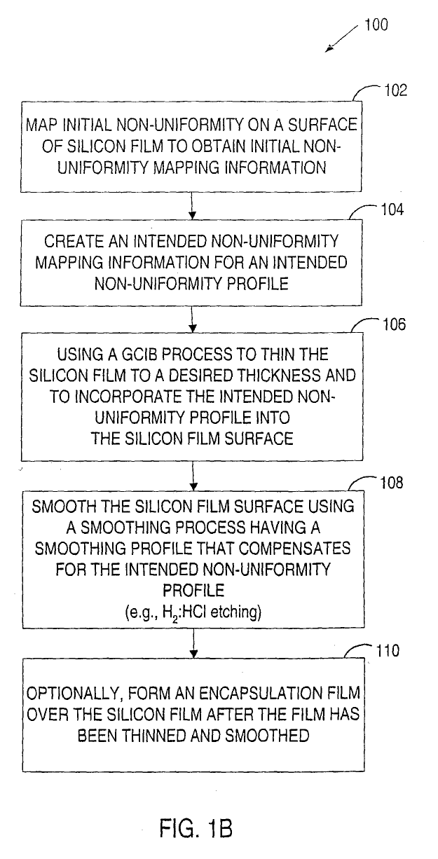

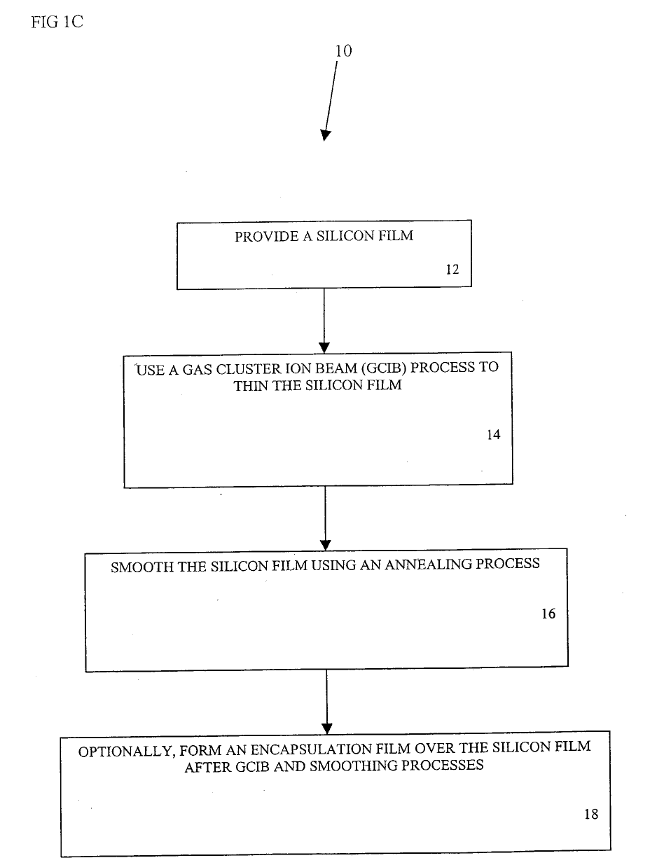

FIG. 1A illustrates an exemplary method 11 of treating a silicon film. In the method 11, at operation 13, a silicon film is provided. An initial mean thickness of the silicon film is obtained at operation 15 using conventional methods such as a reflectometry technique. An initial non-uniformity profile for the silicon film is obtained at operation 17 using conventional methods such as the reflectometry technique used for the operation 15. The silicon film is then thinned to a thickness and at the same time, an intended non-uniformity profile is incorporated into the silicon film surface at operation 19. A process such as the GCIB etching process is used to thin the silicon film and incorporate the intended non-uniformity profile. At operation 21, the silicon film surface is smoothed using a smoothing process having a smoothing profile that compensates for the intended non-uniformity profile. An example of such a smoothing process is an H₂:HCl etching process. Thinning the silicon film with the GCIB etching process alone gives good uniform film thickness but not surface smoothness. Smoothing the silicon film alone does not give a uniform thickness across the film. Further, a smoothing process such as the H₂:HCl etching process inherently has an etching profile. The GCIB etching process can be used to incorporate an intended non-uniformity profile that will be smoothed out by the H₂:HCl etching process. The resulting film is thinned to a uniform and control thickness and a good smoothness across the film. Optionally, an encapsulation film (e.g., a silicon dioxide film) is formed over the silicon film that has been treated with the GCIB etching and the smoothing processes as illustrated at operation 23.

FIG. 1B illustrates an exemplary method 100 of treating a silicon film. In the method 100, the silicon film is first thinned to a thickness using a GCIB etching process and then smoothed using a smoothing process. A smoothing process that can be used includes an H₂:HCl etching process.

At operation 102 of the method 100, the initial non-uniformity of the surface of the silicon film is determined. A conventional measuring technique is used to map the initial non-uniformity of the silicon film surface to obtain the initial non-uniformity mapping information. At operation 104, a predetermined or an intended non-uniformity mapping information for an intended non-uniformity profile is created. This intended non-uniformity profile is incorporated into the silicon film surface during the thinning process of the silicon film.

At operation 106, a GCIB etching process (see below) is used to thin the silicon film to a thickness and to incorporate the intended non-uniformity profile into the silicon film surface. In one embodiment, a GCIB is directed toward the silicon film surface. The GCIB is modulated depending on the initial non-uniformity mapping information and the intended non-uniformity mapping information such that the silicon film is thinned and the intended non-uniformity profile is incorporated into the silicon film.

At operation 108, the thinned silicon film is smoothed out using a smoothing process that has a smoothing profile that compensates for the intended non-uniformity profile. The smoothing profile of the smoothing process compensates for the intended non-uniformity in that the smoothing process smoothes out the intended non-uniformity profile. To smooth out the thinned silicon film, an H₂:HCl etching process is used wherein the silicon film surface is etched a high temperature and in the presence of a hydrogen (H₂) and hydrochloric acid (HCl) gas mixture. The method 100 takes advantage of the fact that the GCIB etching process can thin a film to a uniform thickness across the film but not necessarily leaves a very smooth surface. The method 100 further takes advantage of the fact that (1) the H₂:HCl etching process etches a film with an etching profile that can be determined and (2) a film treated by the H₂:HCl etching process has a very smooth surface. Combining the GCIB etching process with the H₂:HCl etching process, the method 100 thins the silicon film to a thickness and incorporates the intended non-uniformity profile that is smoothed out using the H₂:HCl etching process. The silicon film treated with the GCIB and the H₂:HCl etching processes is very smooth and has a uniform thickness. In one embodiment, the silicon film is less than 200 Å thick and is very smooth (e.g., having a surface roughness less than 1 Å RMS).

At operation 110, an encapsulation film (e.g., a silicon dioxide film) is optionally formed over the silicon film that has been treated with the GCIB etching and the smoothing processes. In one embodiment, to form the encapsulation layer on the silicon film, an ozone (O3) gas is used. The silicon film is “soaked” with the ozone gas. The ozone gas forms a stable and clean oxide layer on the silicon film. The silicon film is thus protected from contaminants by an oxide film that has a high density, high purity, and high quality.

The exemplary methods of the present invention optimize advantages of both the GCIB etching process and the smoothing process. The GCIB etching process has an excellent thickness control. And, the smoothing process has an excellent smoothness control. The silicon film treated with these two processes has a uniform thickness and a smooth surface. Additionally, the silicon film is protected with a high quality encapsulation film.

As a thinning technique, the GCIB etching process has an advantage in that the GCIB etching process can selectively remove material to thin a film to any thickness. A uniform film thickness is achieved by several steps. Based on the measured initial film thickness, more or less of the film material is removed at particular locations. A profile of the initial non-uniformity of the silicon film is programmed into the GCIB etching process. A thickness and a desired profile are also programmed into the GCIB etching process. This initial non-uniformity profile is then considered for the etching or the thinning of the film to obtain the thickness and the desired profile. Thus, the GCIB etching process allows for more or less removal of the materials according to the initial non-uniformity profile to thin the silicon film to obtain the thickness and desired profile. In one embodiment, the GCIB process' ability to control the thickness of the film allows for an incorporation of a particular intended non-uniformity profile into the film.

As a smoothing process, the H₂:HCl etching process has excellent smoothness control. For example, the H₂:HCl etching process is very stable and has a known etching profile that can be obtained for a particular etching chamber. Thus, it is easy to create the intended non-uniformity profile that the H₂:HCl etching process can compensate for during the smoothing process.

Thus, the exemplary methods 11 and 100 take advantage of the precise thickness control of the GCIB etching process and the surface smoothing ability of the H₂:HCl etching process.

FIG. 1C illustrates an exemplary method 10 of treating a silicon film. In the method 10, at operation 12, a silicon film is provided. A GCIB etching process is used to thin the silicon film as illustrated at operation 14. At operation 16, the silicon film surface is smoothed using an annealing process. Optionally, an encapsulation film (e.g., a silicon dioxide film) is formed over the silicon film that has been treated with the GCIB etching and the smoothing processes as illustrated at operation 16.

FIG. 1D illustrates an exemplary method 10A of treating a silicon film. In the method 10A, at operation 20, a silicon film is provided. An initial mean thickness of the silicon film is obtained at operation 22 using conventional methods such as a reflectometry technique. An initial non-uniformity profile for the silicon film is obtained at operation 24 using conventional methods such as the reflectometry technique used for the operation 22. The silicon film is then thinned to a thickness using a GCIB etching process as illustrated at operation 26. At operation 28, the silicon film surface is smoothed using an annealing process such as a rapid thermal annealing process. Optionally, an encapsulation film (e.g., a silicon dioxide film) is formed over the silicon film that has been treated with the GCIB etching and the smoothing processes as illustrated at operation 30.

As a smoothing process, a rapid thermal annealing has excellent capability of smoothing a rough surface. The annealing process can smooth a film surface be re-arranging the surface atoms. The annealing process can thus smooth out roughness that is present on the silicon film after being treated by a GCIB etching process.

Thus, the exemplary methods 10 and 10A take advantage of the precise thickness control of the GCIB etching process and the surface smoothing ability of the annealing process.

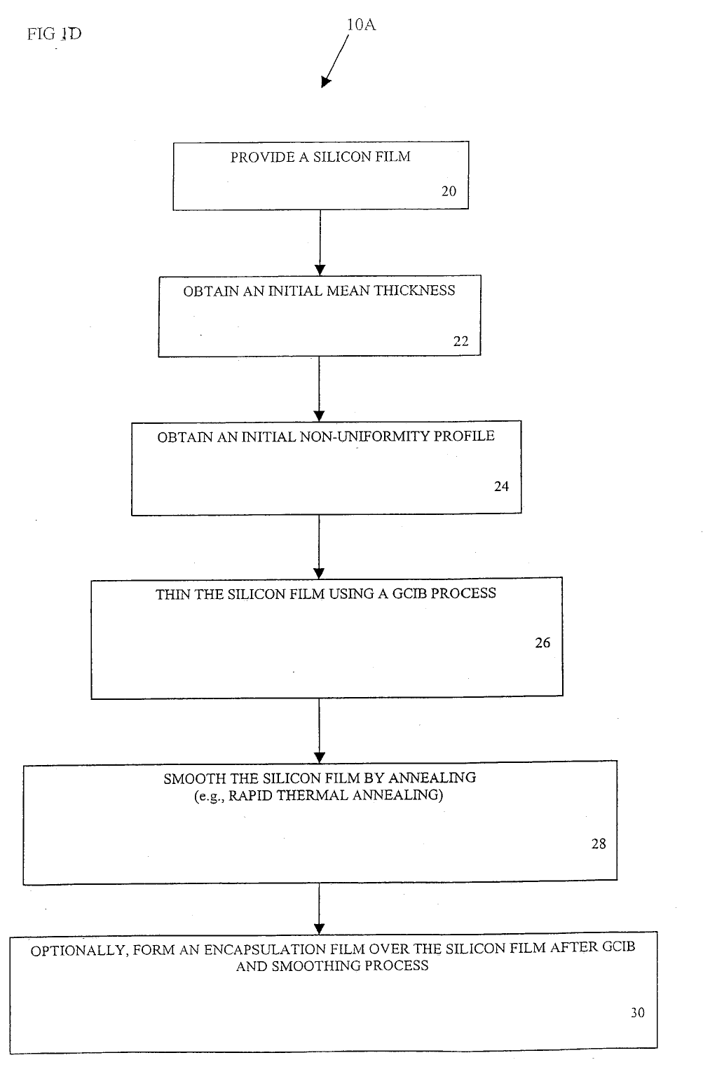

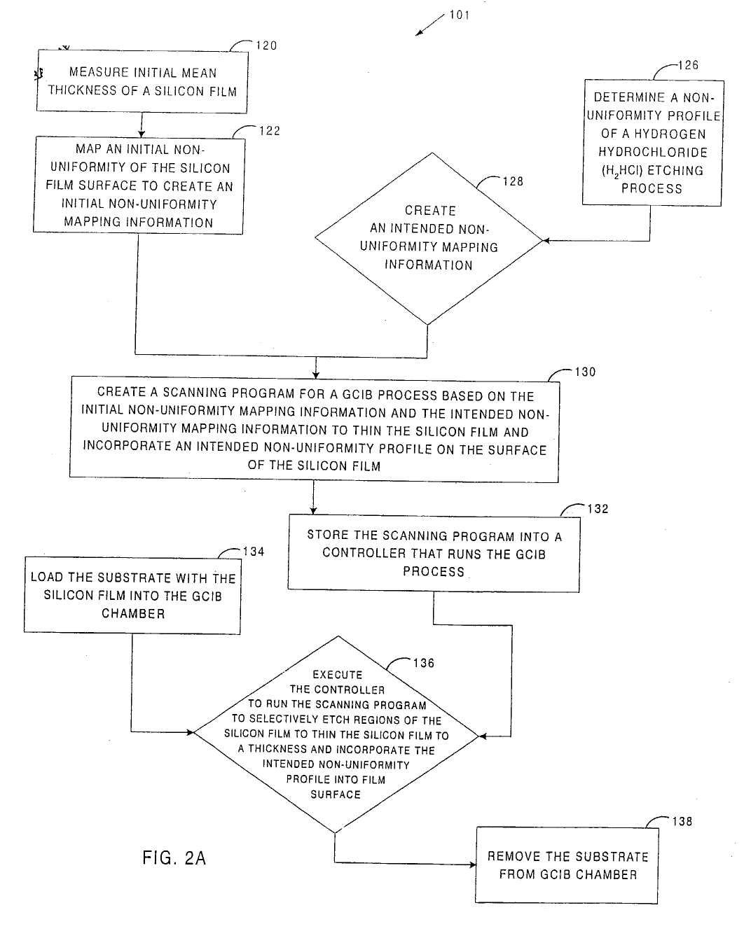

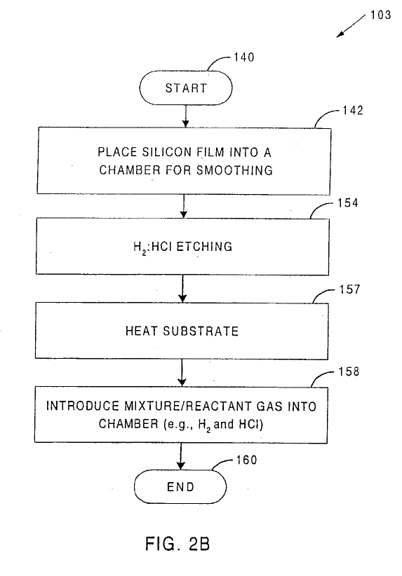

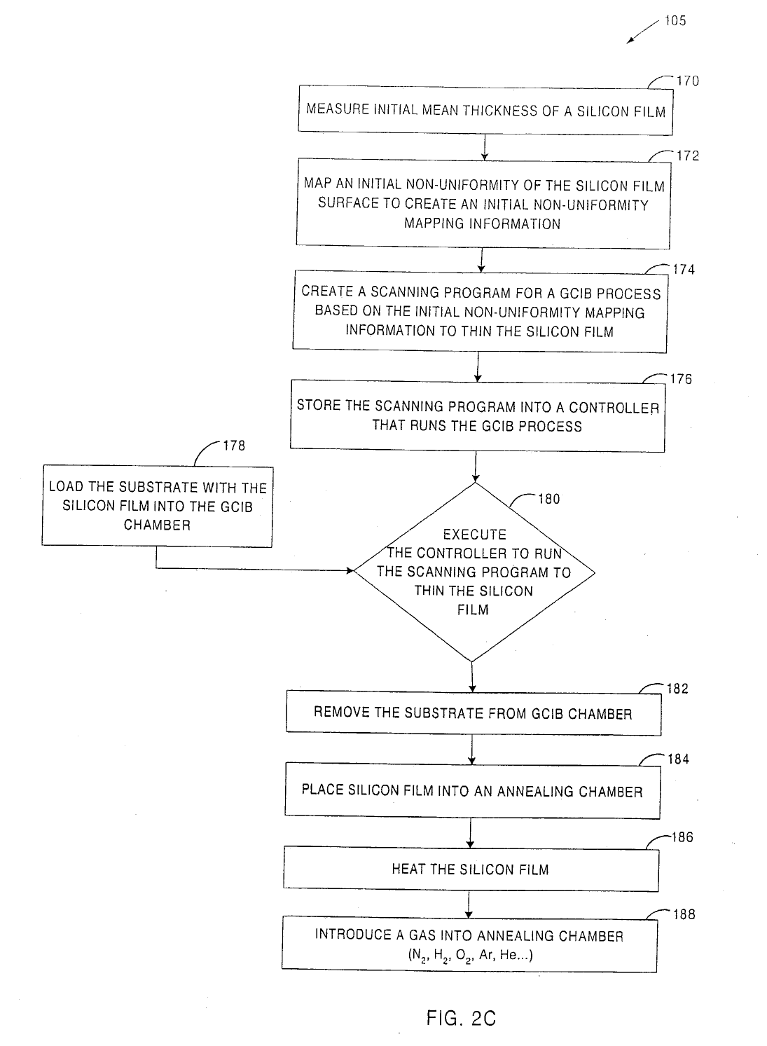

FIG. 2A illustrates another exemplary method, a method 101, of treating a silicon film by thinning while incorporating an intended non-uniformity profile into the surface of the silicon film and then smoothing out the intended non-uniformity profile. In one embodiment, the silicon film is formed on a semiconductor substrate typically used for making semiconductor devices. At operation 120, the initial mean thickness of the silicon film is measured. At operation 122, an initial non-uniformity of the silicon film is mapped to create an initial non-uniformity mapping information. In one embodiment, the initial mean thickness of the silicon film is first calculated. Thickness of various sections across the silicon film are then measured and compared to the initial mean thickness. An initial non-uniformity mapping information is created based on the different thickness across the silicon film. In one embodiment, the initial non-uniformity mapping information indicates a initial non-uniformity profile across the silicon film.

In one embodiment, a non-uniformity profile for the H₂:HCl etching process can be determined at operation 126. The non-uniformity profile for the H₂:HCl etching profile can be determined based on the etching profile of the H₂:HCl etching process for a particular process chamber. In one embodiment, the silicon film's thickness before and after being etched by a particular H₂:HCl etching process is measured with a conventional reflectometry instrument. The thickness measure before and after the hydrogen hydrochloride enables the determination of the particular H₂:HCl etching process.

In one embodiment, at operation 128, an intended non-uniformity mapping information is created. In one embodiment, the intended non-uniformity mapping information is created based on the non-uniformity profile of the H₂:HCl etching process. This intended non-uniformity mapping information indicates the etching profile of the H₂:HCl etching process. In another embodiment, the intended non-uniformity mapping information simply represents a roughness on a surface that the annealing process is capable of smoothing out.

At operation 130, a scanning program for a GCIB etching process is created. This scanning program is used to thin the silicon film and incorporate an intended non-uniformity profile into the silicon film surface. The scanning program is created based on the initial non-uniformity mapping information and the intended non-uniformity mapping information created at operation 128. In one embodiment, at operation 132, the scanning program created at operation 130 is stored into a controller that runs the GCIB etching process.

In one exemplary embodiment, the substrate with the silicon film to be etched or thinned is loaded into the GCIB chamber at operation 134. The controller is then executed as illustrated operation 136. When the controller is executed, the scanning program is executed to selectively etch regions of the silicon film to achieve the thickness and to incorporate the intended non-uniformity profile into the silicon film surface. The scanning program dictates how much material from a particular region that is removed to thin the silicon film to the thickness and at the same time incorporate the intended non-uniformity profile into the surface of the silicon film. At operation 138, the substrate is removed from the GCIB chamber once the silicon film has been thinned. The silicon film that has been processed according to the method 101 as discussed above is referred to as a GCIB treated silicon film.

The GCIB treated silicon film is then smoothed to produce a thinned and smoothed silicon film. In one embodiment, a method 103 described in FIG. 2B is used to smooth the GCIB treated silicon film. At operation 142 of the method 103, the substrate with the GCIB treated silicon film is placed in a smoothing chamber. The GCIB treated silicon film is smoothed out using an H₂:HCl etching process as illustrated at operation 154. In one embodiment, the H₂:HCl etching process includes an addition of a silicon source gas (e.g., silane, disilane, etc.).

In one embodiment, the substrate is heated to a temperature between 1000° C. to 1300° C. for the H₂:HCl etching process as illustrated at operation 157. While the substrate is heated, the surface of the treated GCIB silicon film is exposed to a gas mixture comprising of hydrogen (H₂) and hydrochloric gas (HCl) gas as illustrated at operation 158. The relatively high temperature used during the surface treatment is sufficient to increase silicon mobility and thereby causing the silicon in high areas of peaks to migrate to low areas or valleys in the silicon film. Simultaneously, with the silicon migration, the gas mixture removes the top regions of the silicon surface resulting in a smoothing of the silicon surface. At operation 160, after the surface of the silicon film has been sufficiently smoothed to a roughness value of less than 1 Å RMS when the H₂:HCl etching process is ended. In one embodiment, the H₂:HCl etching process etches and smoothes the silicon film. The thickness of the silicon film is reduced at a rate of 0.1 Å/second to more than 1000 Å/second depending on the proportion of the HCl in the gas mixture.

In one embodiment, a conventional chemical vapor deposition chamber can be used for the H₂:HCl etching process. In another example, a single wafer deposition chamber is used. In yet other examples, any apparatus conventionally used for a H₂:HCl etching process can be used to smooth the GCIB treated silicon film. An example of a single wafer deposition chamber that can be used includes the Applied Materials single wafer atmospheric “EPI” tool known as the “EPI Centura”. An example of a single wafer deposition chamber will be described below.

As mentioned, the H₂:HCl etching process has an etching profile that compensates for the intended non-uniformity profile. Thus, the etching profile of the H₂:HCl etching process smoothes out the intended non-uniformity profile to leave the GCIB treated silicon film with a smooth surface. In one embodiment, an Atomic Force Microscopy (AFM) is used to measure the smoothness (by measuring the surface roughness) of the silicon film after it is treated with the GCIB and the H₂:HCl etching processes. In one embodiment, the final film has a surface roughness less than 1 Å RMS.

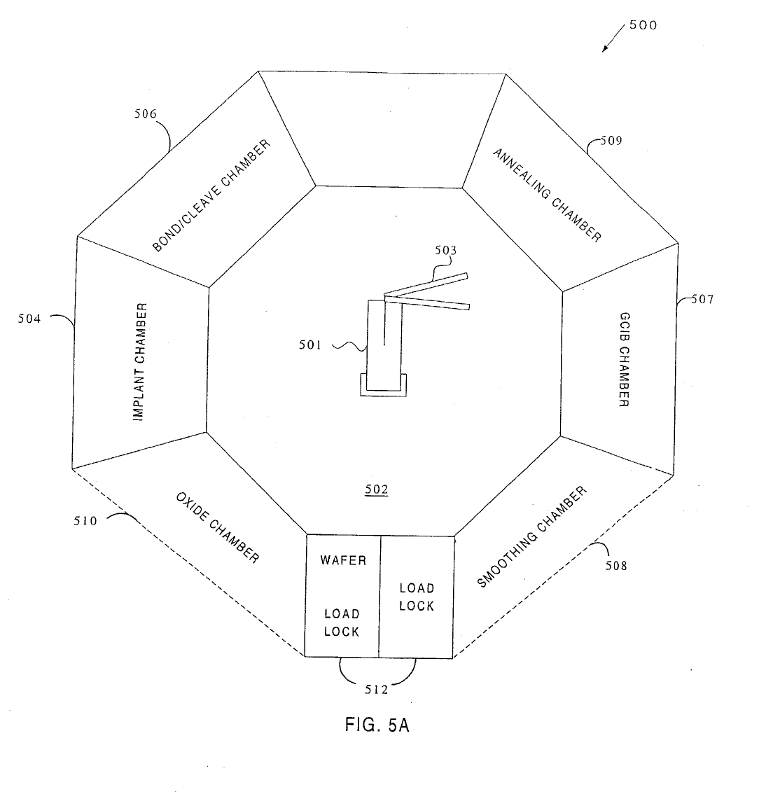

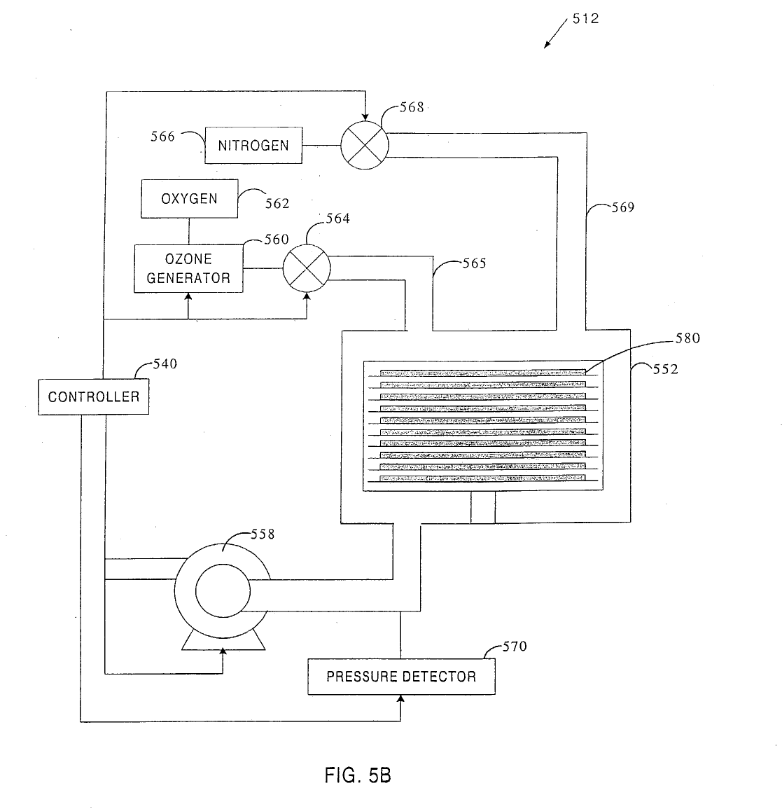

In another exemplary embodiment, the silicon film that is thinned and smoothed according to the exemplary embodiments described above can act as a layer that other silicon films can be deposited or formed thereon. In one embodiment, an encapsulation film is formed on the silicon film to protect the silicon film. In this embodiment, the substrate is placed in a chamber that is coupled to an ozone generator that can generate an ozone gas from an oxygen source gas (see below FIG. 5B). The oxygen source gas may comprise a substantially pure oxygen gas. In one embodiment, the oxygen gas has a purity of 99.999%. The ozone generator supplies the ozone gas into the chamber to soak the silicon film with the ozone gas. The encapsulation film is a clean and stable silicon dioxide formed on the silicon film. The encapsulation film protects the silicon film from contaminants so that the silicon film may be exposed to air until being used to form devices therein and thereon. An example of a chamber that can be used to form the encapsulation film can be found in U.S. Pat. No. 6,376,387, which is assigned to Applied Materials.

FIG. 2C illustrates another exemplary method, a method 105, of treating a silicon film. In one embodiment, the silicon film is formed on a semiconductor substrate typically used for making semiconductor devices. At operation 170, the initial mean thickness of the silicon film is measured. At operation 172, an initial non-uniformity of the silicon film is mapped to create an initial non-uniformity mapping information. In one embodiment, the initial mean thickness of the silicon film is first calculated. Thickness of various sections across the silicon film are then measured and compared to the initial mean thickness. An initial non-uniformity mapping information is created based on the different thickness across the silicon film. In one embodiment, the initial non-uniformity mapping information indicates an initial non-uniformity thickness profile across the silicon film.

At operation 174, a scanning program for a GCIB etching process is created using techniques known in the art. This scanning program is used to thin the silicon film. The scanning program is created based on the initial non-uniformity mapping information and a thickness that the silicon film needs to be thinned to. In one embodiment, at operation 176, the scanning program created at operation 174 is stored into a controller that runs the GCIB etching process.

In one exemplary embodiment, the substrate with the silicon film to be etched or thinned is loaded into the GCIB chamber at operation 178. The controller is then executed as illustrated operation 180. When the controller is executed, the scanning program is executed to selectively etch regions of the silicon film to achieve the thickness that the silicon film needs to be at. In one embodiment, the silicon film is thinned to a thickness less than 200 Å. The scanning program dictates how much material from a particular region that is removed to thin the silicon film to the thickness and at the same time incorporate the intended non-uniformity profile into the surface of the silicon film. At operation 182, the substrate is removed from the GCIB chamber once the silicon film has been thinned.

As can be seen the exemplary method 105 the GCIB etching process allows the etching of the silicon film to the thickness by etching more or less at a certain location of the silicon film depending on the initial non-uniformity mapping information and the intended non-uniformity mapping information that have been stored into the scanning program. The GCIB etching process has the ability to finely control the etching of the silicon film to a thin or even an ultra thin level. For example, the silicon film can be etched or thinned to a thickness less than 200 Å. The silicon film that has been processed according to the method 105 as discussed above is referred to as a GCIB treated silicon film.

The GCIB treated silicon film is then smoothed to produce a thinned and smoothed silicon film. In one embodiment, the substrate with the GCIB treated silicon film is placed in an annealing chamber as illustrated at operation 184.

The annealing process can be carried out using a conventional rapid thermal annealing process chamber (annealing chamber). In one embodiment, as shown at operation 186, the substrate is heated to a temperature between 1000° C. and 1300° C. The annealing process can be carried out at a sub-atmospheric pressure, for example, less than 760 Torr. Additionally, as shown at operation 188, a gas mixture containing gases such as hydrogen (H₂), oxygen (O₂), nitrogen (N₂), helium (He), or argon (Ar) is introduced into the annealing chamber. In an embodiment where the annealing is carried out with a mixture containing H₂ gas, during the annealing process, the annealing process induces a surface diffusion phenomenon of silicon atoms leading to smoothing the silicon film surface. The substrate is annealed for a predetermined amount of time of annealing, for example, 10 to 60 seconds. The annealing process is ended at operation 190. In one embodiment, the substrate is annealed for a sufficient amount of time to obtain a roughness value of less than 1 Å RMS.

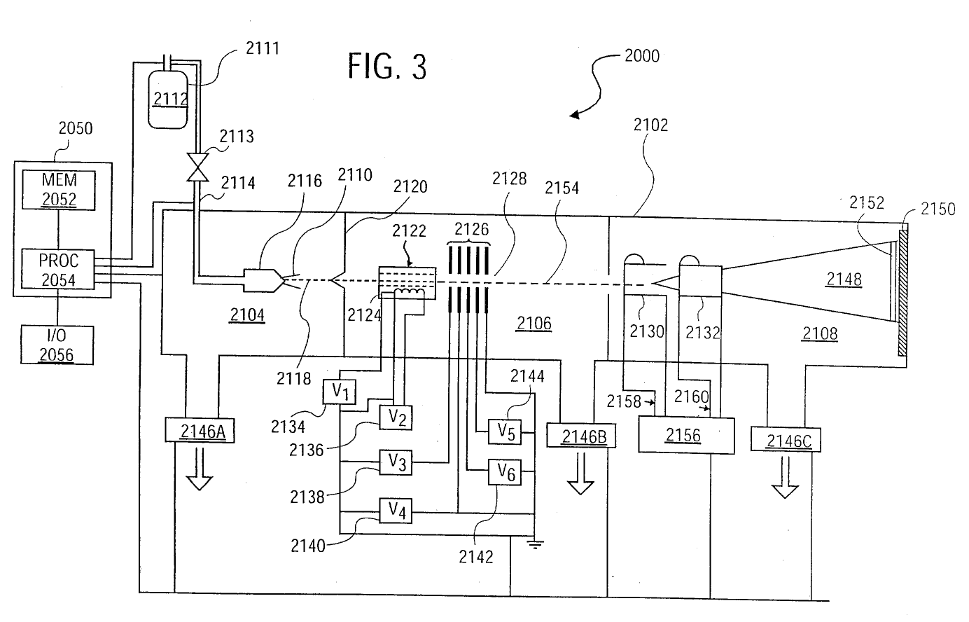

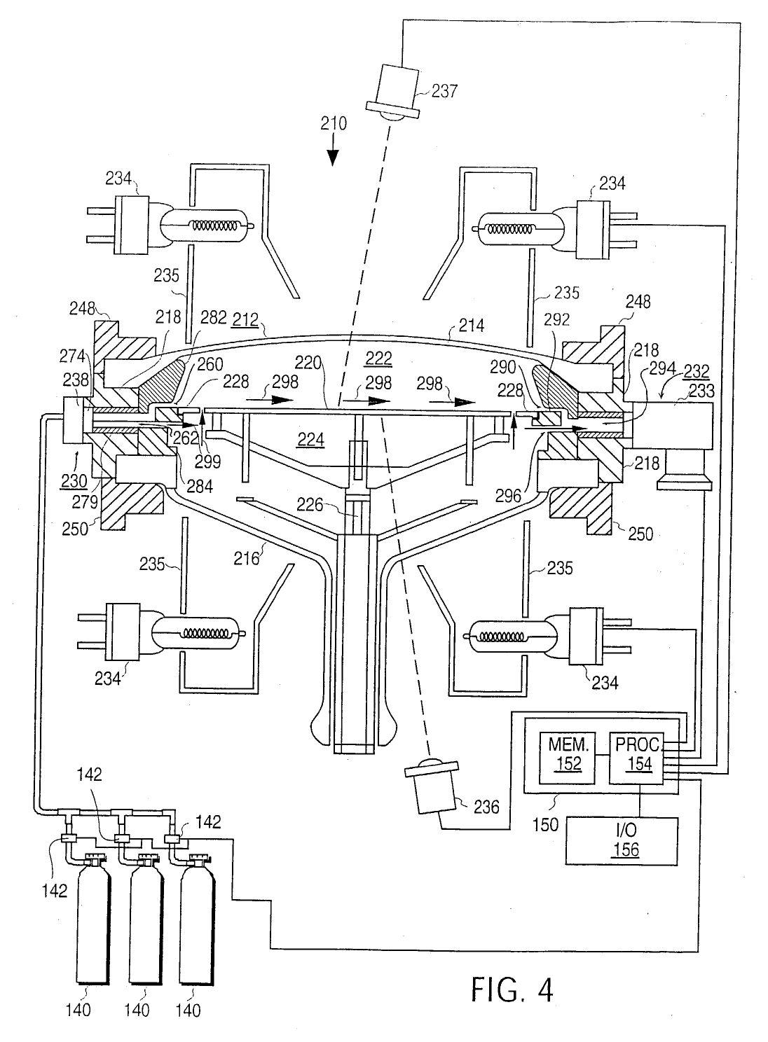

FIG. 3 illustrates an exemplary GCIB apparatus 2000 which can be used to thin the silicon film in accordance with some of the exemplary embodiments described above, for example, the method 100 and the method 101. FIG. 4 illustrate an exemplary thermal processing apparatus 210 in which some of the embodiments can be implemented, for example, the method 103 described above. An example of such an apparatus shown FIG. 4 is the Applied Materials single wafer atmospheric “EPI” tool known as the “EPI Centura”. It is to be appreciated that other processing chambers can also be used for the exemplary embodiments of the present invention such as a resistively heated single wafer deposition chamber or a rapid thermal annealing (RTA) chamber. These chambers are well known in the art thus, descriptions of these chambers are not included.

Returning to FIG. 3, in one exemplary embodiment, a conventional GCIB apparatus 2000 includes a vacuum vessel 2102, which is divided into three communicating chambers, a source chamber 2104, an ionization/acceleration chamber 2106, and a processing chamber 2108. The GCIB apparatus 2000 includes three vacuum pumping systems, 2146A, 2146B, and 2146C, which are used to evacuate the pressure in the vessel 2102. The GCIB apparatus 2000 is further coupled to a gas source, cylinder 2111 to supply gas into the vessel 2102. The vessel 2102 includes an ionizer 2122 to ionize the gas clusters and a filament power supply 2136 to accelerate the gas clusters. The vessel 2102 further includes a substrate holder 2150, which can hold a substrate 2152. Further details of a conventional GCIB apparatus can be found in a PCT Application PCT/US01/21620 (WO 02/05315), published Jan. 17, 2002 and U.S. Pat. No. 6,207,282.

In another exemplary embodiment, the source chamber 2104, the ionization/acceleration chamber 2106, and the processing chamber 2108 are evacuated to suitable operating pressures by the vacuum pumping systems 2146A, 2146B, and 2146C, respectively. The chambers are typically operated under a sub-atmospheric pressure. To begin the process, a condensable source gas 2112 stored in the cylinder 2111 is admitted under pressure through gas metering valves 2113 and gas feed tube 2114 into the source chamber 2104 of the vessel 2102. Suitable condensable source gases 2112 include, but are not necessarily limited to argon (AR), nitrogen (N₂), carbon dioxide (CO₂), and oxygen (O₂). The condensable source gas 2122 enters a stagnation chamber 2116 and is injected into the substantially lower pressure vacuum through a properly shaped nozzle 2110. The injected condensable source gas 2112 forms a supersonic gas jet 2118. Expansion in the gas jet 2118 results in cooling of the gas jet 2118 and causes a portion of the gas jet 2118 to condense into clusters, each of which consisting of from several to several thousand weakly bound atoms or molecules. The source chamber 2104 also includes a gas skimmer aperture 2120, which partially separates the gas molecules that have not condensed into a cluster jet from the cluster jet so as to minimize pressure in the downstream regions. High pressures would be detrimental to the ionizer 2122, the high voltage electrodes 2126, and the process chamber 2108.

After the supersonic gas jet 2118 containing gas clusters have been formed, the clusters are ionized in an ionizer 2122 in the ionization/acceleration chamber 2106. The ionizer 2122 is typically an electron impact ionizer that produces thermoelectrons from one or more incandescent filaments 2124. The ionizer 2122 also accelerates and directs the electrons causing them to collide with the gas clusters in the gas jet 2118, when a gas jet 2188 passes through the ionizer 2122. The electron impact ejects the electrons from the clusters, causing a portion of the clusters to become positively ionized. A set of suitably biased high voltage electrodes 2126 extracts the cluster ions from the ionizer to form a beam. The high voltage electrode 2126 then accelerates the cluster ions in a beam in to a desired energy (typically from 1 keV to several tens of keV) and focuses the cluster ions them to form a GCIB 2128 having an initial trajectory 2154.

A filament power supply 2136 included in the ionizer provides a voltage V₂ to heat the ionizer incandescent filament 2124. An anode power supply 2134 provides a voltage V₁ to accelerate thermoelectrons emitted from the filament 2124 to cause the thermoelectrons to bombard the cluster containing gas jet 2118 to produce the ions.

An extraction power supply 2138 coupling to the high voltage electrodes 2126 provides a voltage V₃ to bias a high voltage electrode to extract ions from the ionizing region of ionizer 2122 and to form the GCIB 2128. An accelerator power supply 2140 provides a voltage V₄ to bias a high voltage electrode with respect to the ionizer 2122 so as to result in a total GCIB acceleration energy equal to the V₄ electron volts (eV) and, lens power supplies 2142 and 2144 may be provided to bias high voltage electrodes with potentials V₆ and V₅, respectively, to focus the GCIB 2128.

In one exemplary embodiment, a substrate 2152, is held on a substrate holder 2150, as illustrated in FIG. 3. The substrate 2152 can be a semiconductor substrate (e.g., a silicon wafer that has a silicon film that needs to be treated using the GCIB etching process. In one embodiment, the substrate 2152 is exposed within the path of the GCIB 2128. In one exemplary embodiment, a scanning system is used to uniformly scan the GCIB 2128 across large areas of the substrate 2152. In this embodiment, two pairs of orthogonally oriented electrostatic scan plates 2130 and 2132 are included in the processing chamber 2108. The electrostatic scan plates 2130 and 2132 can be utilized to produce a raster or other scanning pattern across the desired processing area on the substrate 2152. When beam scanning is performed, a scan generator 2156 provides X-axis and Y-axis scanning signal voltage to the pairs of electrostatic scan plates 2130 and 2132 through lead pairs 2158 and 2160 respectively. The scanning signal voltages are commonly triangular waves of different frequencies that cause the GCIB 2128 to be converted into a scanned GCIB 2148, which scans the entire surface of the substrate 2152.

In another exemplary embodiment, the GCIB apparatus 2000 shown in FIG. 3 includes a system controller 2050, which controls various operations of the apparatus 2000. In one exemplary embodiment, the system controller 2050 includes a machine-readable medium 2052 such as a hard disk drive (indicated in FIG. 4 as “memory 2052”) or a floppy disk drive. The system controller 2050 also includes a processor 2054. An input/output device 2056 such as a CRT monitor and a keyboard is used to interface between a user the and the system controller 2050.

The processor 2054 contains a single board computer (SBC), analog and digital input/output boards, interface boards and stepper motor controller board. Various parts of the GCIB apparatus 2000 conform to the Versa Modular Europeans (VME) standard which defines board, card cage, and connector dimensions and types. The VME standard also defines the bus structure having a 16-bit data bus and 24-bit address bus.

In one exemplary embodiment, the system controller 2050 controls all of the activities of the GCIB apparatus 2000. The system controller executes system control software, which is a computer program stored in the machine-readable medium 2052. Preferably, the machine-readable medium 2052 is a hard disk drive, but the machine-readable medium 2052 may also be other kinds of memory stored in other kinds of machine-readable media such as one stored on another memory device including, for example, a floppy disk or another appropriate drive. The computer program includes sets of instructions that dictate the parameters of a particular GCIB etching process.

The process for etching or thinning a silicon surface in accordance with the present invention can be implemented using a computer program product (program), which is stored in the machine-readable medium 2052 and, is executed by the processor 2054. The computer program code can be written in any conventional computer readable programming language, such as, 68000 assembly language, C, C++, Pascal, Fortran, or others. Suitable program code is entered into a single file, or multiple files, using a conventional text editor, and stored or embodied in a computer usable medium, such as a memory system of the computer. If the entered code text is in a high level language, the code is compiled, and the resultant compiler code is then linked with an object code of precompiled windows library routines. To execute the linked compiled object code, the system user invokes the object code, causing the computer system to load the code in memory, from which the CPU reads and executes the code to perform the tasks identified in the program. Also stored in the machine-readable medium 2052 are process parameters to carry out the etching or thinning of the silicon films in accordance with the exemplary embodiments of the present invention.

In one embodiment, the program includes instructions for receiving an initial non-uniformity mapping information for the silicon film and an intended non-uniformity mapping information to be incorporated into the silicon film. The program may include instructions for receiving a scanning program which is created based on the initial non-uniformity mapping information and the intended non-uniformity mapping information. In an embodiment, the program includes instructions for creating the scanning program based on the initial non-uniformity mapping information and the intended non-uniformity mapping information. The program may include instructions for treating a silicon film such as to thin the silicon film to a thickness and to incorporate an intended non-uniformity profile into the silicon film as mentioned above.

FIG. 4 illustrates an exemplary apparatus for smoothing the intended non-uniformity profile that is incorporated into the silicon film using the GCIB etching process described above. In one embodiment, an H₂:HCl etching process is carried out in the apparatus shown in this figure. FIG. 4 illustrates an apparatus 210, which is a deposition reactor that can be used to smooth out the silicon film surface that has the intended non-uniformity profile. The apparatus 210 comprises a deposition chamber 212 having an upper dome 214, a lower dome 216, and a sidewall 218 between the upper and lower domes 214 and 216. Cooling fluid (not shown) is circulated through sidewall 218 in order to cool the sidewall 218. An upper liner 282 and a lower liner 284 are mounted against the inside surface of the sidewall 218. The upper and lower domes 214 and 216 are made of a transparent material to allow heating light to pass through into the chamber 212.

Within the chamber 212 is a flat, circular susceptor 220 for supporting a wafer (or a semiconductor substrate) in a horizontal position. The susceptor 220 extends transversely across the chamber 212 at the sidewall 218 to divide the chamber 212 into an upper portion 222 above the susceptor 220 and a lower portion 224 below the susceptor 220. The susceptor 220 is mounted on a shaft 226 which extends perpendicularly downwardly from the center of the bottom of the susceptor 220. The shaft 226 is connected to a motor (not shown) which rotates the shaft 226 in order to rotate the susceptor 220. The wafer supported by the susceptor 220 is rotated throughout the smoothing process. An annular preheat ring 228 is connected at its outer periphery to the inside periphery of the lower liner 284 and extends around the susceptor 220. The pre-heat ring 228 is in the same plane as the susceptor 228 with the inner edge of the pre-heat ring 228.

An inlet manifold 230 is positioned in the side of the chamber 212 and is adapted to admit gas from a source of gas or gases, such as tanks 140, into the chamber 212. An outlet port 232 is positioned in the side of chamber 212 diagonally opposite the inlet manifold 230 and is adapted to exhaust gases from the deposition chamber 212.

A plurality of high intensity lamps 234 are mounted around the chamber 212 and direct their light through the upper and lower domes 214 and 216 onto the susceptor 220 (and the preheat ring 228) to heat the susceptor 220 (and the preheat ring 228). The susceptor 220 and the preheat ring 228 are made of a material, such as silicon carbide, coated graphite which is opaque to the radiation emitted from the lamps 234 so that they can be heated by radiation from the lamps 234. The upper and lower domes 214 and 216 are made of a material which is transparent to the light of the lamps 234, such as clear quartz. The upper and lower domes 214 and 216 are generally made of quartz because quartz is transparent to light of both visible and IR frequencies. Quartz exhibits a relatively high structural strength; and it is chemically stable in the process environment of the deposition chamber 212. Although lamps are the preferred elements for heating wafers in deposition chamber 212, other methods may be used such as resistance heaters and Radio Frequency inductive heaters.

An infrared temperature sensor 236 such as a pyrometer is mounted below the lower dome 216 and faces the bottom surface of the susceptor 220 through the lower dome 216. The temperature sensor 236 is used to monitor the temperature of the susceptor 220 by receiving infrared radiation emitted from the susceptor 220 when the susceptor 220 is heated. A temperature sensor 237 for measuring the temperature of a wafer may also be included if desired.

An upper clamping ring 248 extends around the periphery of the outer surface of the upper domes 214. A lower clamping ring 250 extends around the periphery of the outer surface of the lower dome 216. The upper and lower clamping rings are secured together so as to clamp the upper and lower domes 214 and 216 to the sidewall 218.

The gas inlet manifold 230 included in the apparatus 210 feeds process gas (or gases) into the chamber 212. The gas inlet manifold 230 includes a connector cap 238, a baffle 274, and an insert plate 279 positioned within the sidewall 218. Additionally, the connector cap 238, the baffle 274, and the insert plate 279 are positioned within a passage 260 formed between upper liner 282 and lower liner 284. The passage 260 is connected to the upper portion 222 of chamber 212. Process gas (or gases) are introduced into the chamber 212 from the gas cap 238, the gas or gases are then flown through the baffle 274, through the insert plate 279, and through the passage 260 and then into the upper portion 222 of chamber 212.

The apparatus 210 also includes an independent gas inlet 262 for feeding a purge gas, such as hydrogen (H₂) or Nitrogen (N₂), into the lower portion 224 of deposition chamber 212. As shown in FIG. 4, the purge gas inlet 262 can be integrated into gas inlet manifold 230, if desired, as long as a physically separate and distinct passage 262 through the baffle 274, the insert plate 279, and the lower liner 284 is provided for the purge gas, so that the purge gas can be controlled and directed independent of the process gas. The purge gas inlet 262 need not be integrated or positioned along with deposition gas inlet manifold 230, and can, for example, be positioned on the reactor 210 at an angle of 90° from a deposition gas inlet manifold 230.

As mentioned, the apparatus 210 also includes a gas outlet 232. The gas outlet 232 includes an exhaust passage 290, which extends from the upper chamber portion 222 to the outside diameter of sidewall 218. The exhaust passage 290 includes an upper passage 292 formed between the upper liner 282 and the lower liner 284 and which extends between the upper chamber portion 222 and the inner diameter of sidewall 218. Additionally, the exhaust passage 290 includes an exhaust channel 294 formed within the insert plate 279 positioned within sidewall 218. A vacuum source, such as a pump (not shown) for creating low or reduced pressure in the chamber 212 is coupled to the exhaust channel 294 on the exterior of sidewall 218 by an outlet pipe 233. The process gas (or gases) fed into the upper chamber portion 222 is exhausted through the upper passage 292, through the exhaust channel 294 and into the outlet pipe 233.

The gas outlet 232 also includes a vent 296, which extends from the lower chamber portion 224 through lower liner 284 to the exhaust passage 290. The vent 296 preferably intersects the upper passage 292 through the exhaust passage 290 as shown in FIG. 4. The purge gas is exhausted from the lower chamber portion 224 through the vent 296, through a portion of the upper chamber passage 292, through the exhaust channel 294, and into the outlet pipe 233. The vent 296 allows for the direct exhausting of the purge gas from the lower chamber portion to the exhaust passage 290.

According to some exemplary embodiment of the present invention, the process gas or gases 298 are fed into the upper chamber portion 222 from gas inlet manifold 230. In some exemplary embodiments, the process gas is defined as the gas or gas mixture which acts to remove, treat, or deposit a film on a wafer or a substrate that is placed in chamber 212. In one embodiment, the process gas comprises a hydrochloric (HCl) gas and an gas, such as H₂ In this example the hydrochloric gas and the H₂ gas are used as an etchant mixture to smooth the silicon surface of the silicon film that has been thinned using the GCIB etching process that has been described above.

In one exemplary embodiment, while the process gas is fed into the upper chamber portion 222, an inert purge gas or gases 299 are fed independently into the lower chamber portion 224. Purging the chamber 212 with the purge gas 299 prevents an unwanted reaction at the bottom side of the chamber 212 or the bottom side of the susceptor 220.

In one exemplary embodiment, the apparatus 210 shown in FIG. 4 is a single wafer reactor that is also “cold wall” reactor. The sidewall 218 and upper and lower liners 282 and 284, respectively, are at a substantially lower temperature than the preheat ring 228 and the susceptor 220 (and a wafer placed thereon) during processing. For example, when a H₂:HCl etching process occurs at a process temperature between 1000° C. and 1300° C. the susceptor and the wafer are heated to a temperature between 1100° C. and 1300° C. while the sidewall and the liners are at a temperature of about 400-600° C. The sidewall 218 and liners 282 and 284 are at a cooler temperature because they do not receive direct irradiation from lamps 234 due to reflectors 235, and because cooling fluid is circulated through the sidewall 218.

In another exemplary embodiment, the processing apparatus 210 shown in FIG. 4 includes a system controller 150, which is similar to the system controller 2050 that controls the GCIB apparatus 2000. The system controller 150 controls various operations of the apparatus 210 such as controlling gas flows into the chamber 212, controlling the substrate's temperature, controlling the susceptor 220's temperature, and controlling the chamber's pressure. In one exemplary embodiment, the system controller 150 includes a machine-readable medium 152 such as a hard disk drive (indicated in FIG. 4 as “memory 152”) or a floppy disk drive. The system controller 150 also includes a processor 154. An input/output device 156 such as a keyboard, a mouse, a light pen, and a CRT monitor, is used to interface between a user the and the system controller 150.

In one exemplary embodiment, the system controller 150 controls all of the activities of the apparatus 210. The system controller executes system control software, which is a computer program stored in the machine-readable medium 152. Preferably, the machine-readable medium 152 is a hard disk drive, but the machine-readable medium 152 may also be other kinds of memory stored in other kinds of machine-readable media such as one stored on another memory device including, for example, a floppy disk or another appropriate drive. The computer program includes sets of instructions that dictate the timing, mixture of gases, chamber pressure, chamber temperature, lamp power levels, susceptor position, and other parameters of a particular smoothing process.

The process for smoothing a silicon surface in accordance with the present invention can be implemented using a computer program product, which is stored in the machine-readable medium 152 and, is executed by the processor 154. The computer program code can be written in any conventional computer readable programming language, such as, 68000 assembly language, C, C++, Pascal, Fortran, or others. Also stored in the machine-readable medium 152 are process parameters such as the process gas flow rates (e.g., H₂ and HCl flow rates), the process temperatures and the process pressure necessary to carry out the smoothing of the silicon films in accordance with the exemplary embodiments of the present invention.

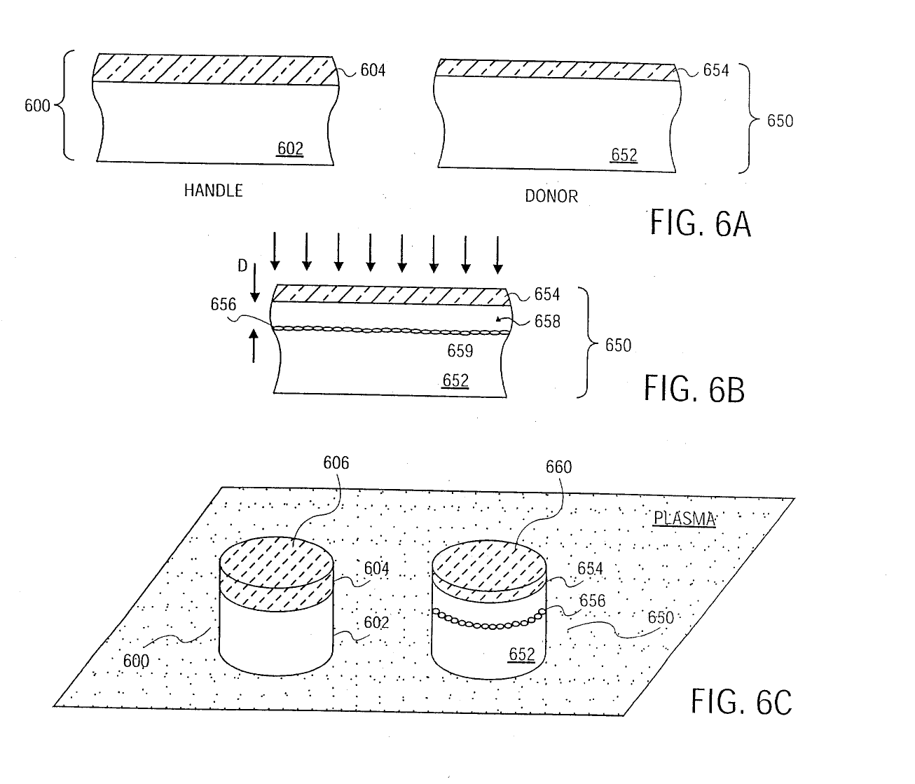

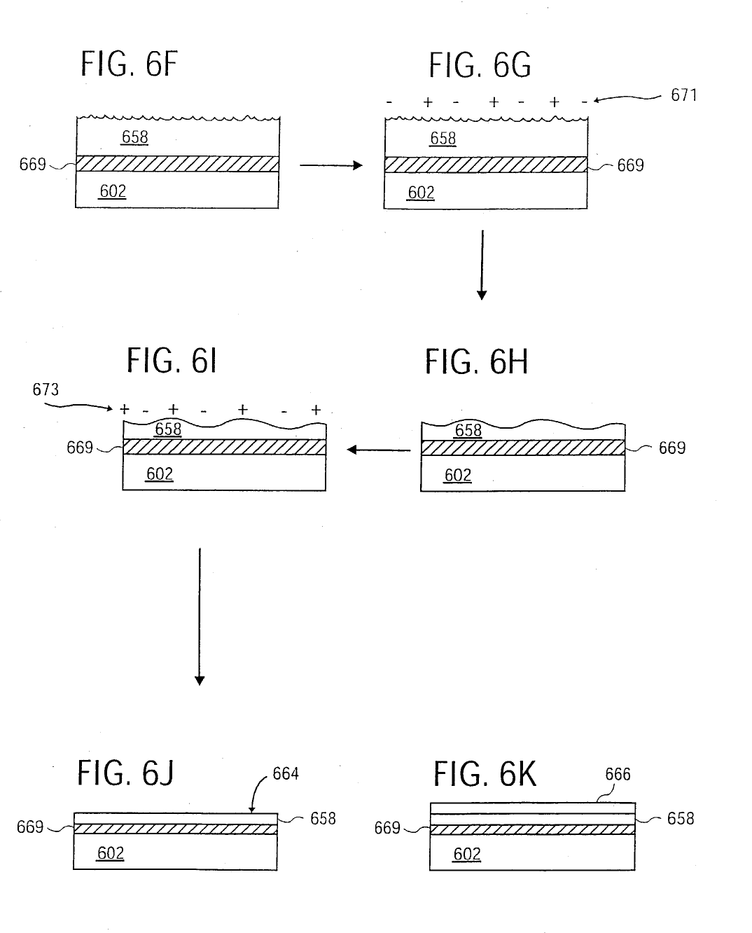

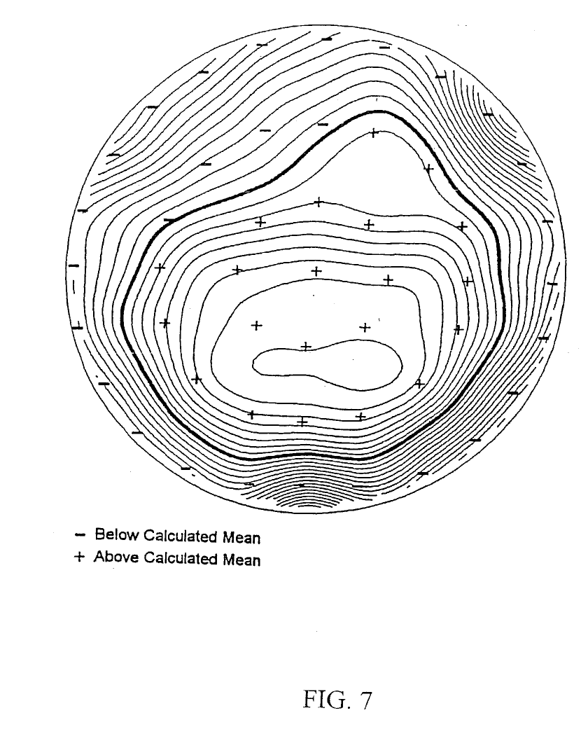

FIGS. 6A-6K illustrate exemplary embodiments in which the combination of the GCIB etching process and the annealing process or the H₂:HCl etching process is used to treat (e.g., thin and then smooth) the silicon film of an SOI substrate or wafer. FIG. 5A accompanies FIGS. 6A-6K in that FIG. 5A illustrates an exemplary cluster tool 500 that can be utilized to carry the exemplary embodiments of FIGS. 6A-6K. The fabrication of the SOI substrate will be described herein below after a brief discussion of the cluster tool 500. Although the exemplary embodiments of the present invention focus on the treatment, e.g., thinning and smoothing, of the silicon film on an insulator substrate, these exemplary embodiments can be used for treating other silicon films without deviating from the scope of the present invention.

The cluster tool 500 includes a transfer chamber 502 to which are attached a plurality of different process apparatuses including, an implant chamber 504, a bond/cleave chamber 506, a GCIB chamber 507, a smoothing chamber 508, an oxide formation chamber 510, an annealing chamber 509, and a loadlock system 512. The GCIB chamber 507 can be the GCIB apparatus 2000 shown in FIG. 3. The smoothing chamber 508 can be the single wafer chamber illustrated as the apparatus 210 shown in FIG. 4. Other chambers, such as a cool down chamber or chambers and/or additional loadlocks, can be attached to transfer chamber 502 as required.

In general, the implant chamber 504 is used to implant ions into a donor wafer to form dislocations in a donor wafer to enable the subsequent cleaving of the silicon film. The bond/cleave chamber 506 is used to bond the handle wafer to the implanted donor wafer and is used to cleave the donor wafer from the handle wafer at the implant dislocation.

The GCIB chamber 507 is used to treat the silicon film that has a rough cleaved surface following the bond and cleave process. The GCIB etching process occurring in the GCIB chamber 507 thins the silicon film, partially smoothes silicon surface (if necessary), and incorporates an intended uniformity profile into the silicon film surface. The silicon film can be thinned to a thickness (e.g., less than 200 Å thick) and the surface of the silicon film has the intended non-uniformity profile incorporated thereon.

The smoothing chamber 508 is used to smooth the surface of the silicon film by smoothing out the intended non-uniformity profile that is incorporated into the silicon film surface. In one embodiment, the smoothing chamber 508 is a process chamber that can be used to carry out a H₂:HCl etching process which can smooth and thin the silicon film. The smoothing chamber 508 can also be used to deposit an epitaxial silicon film on the thinned and smoothed silicon surface if necessary since the smoothing chamber 508 is also a conventional deposition chamber. The smoothing chamber 508 can also be used to smooth the silicon surface of the donor wafer and to deposit additional silicon thereon if desired.

The oxide formation chamber 510 is used to form an oxide on the donor wafer (or handle water if desired). The oxide formation chamber 510 can be for example, a thermal oxidation apparatus such as a furnace or a rapid thermal processor in which a thermal oxide can be grown on a silicon film. Alternatively, the oxide formation chamber 510 can be a chemical vapor deposition (CVD) apparatus.

The loadlock apparatus 512 is used to store wafers or substrates before they are processed in a particular chamber. A transfer chamber 502 is also included in the cluster tool 500. The transfer chamber 502 may include a wafer handling apparatus 501, which includes a wafer-handling clip 503. The wafer handling apparatus 501 and the wafer-handling clip 503 facilitate the transport of wafer substrates in an out of the loadlock apparatus 512 and in and out of a particular process apparatus or chamber. The transfer chamber 502 is further attached to an exhaust system (not shown) such as a pump and a source of inert gas, such as nitrogen (N₂) so that wafers can be transferred between the various process apparatuses or chambers in cluster tool 500 in a reduced pressure ambient or in an inert ambient so that wafers are not exposed to an oxidizing ambient or to sources of contamination.

The loadlock apparatus 512 can further be used as a chamber to form the encapsulation film. In one embodiment, the loadlock apparatus 512 is used to form an encapsulation film on the silicon film after the silicon film is treated with the GCIB etching process and the annealing process or the H₂:HCl etching process to protect the silicon film. In this embodiment, the substrate with the silicon film to be protected is placed in the loadlock apparatus 512. An ozone gas is introduced into the loadlock apparatus 512. The substrate is “soaked” with the ozone gas. The ozone gas forms a stable oxide layer that acts as an encapsulation layer to protect the silicon film. FIG. 5B illustrates an exemplary loadlock apparatus 512 in more detail. Details of an example of an apparatus that can be used to soak the substrate with the ozone gas to form the encapsulation film can be found in U.S. Pat. No. 6,376,387, which is assigned to Applied Materials.

The loadlock apparatus 512 includes a loadlock chamber 552. The loadlock chamber 552 stores from one to a plurality of substrates 580 (e.g., wafers) to be processed by the cluster tool 500. .

The loadlock apparatus 512 further includes an ozone generator 560, which is coupled to an oxygen source gas 562. The oxygen source gas 562 may comprise a substantially pure oxygen gas. In one embodiment, the oxygen gas has a purity of 99.999%. The ozone generator 560 generates an ozone gas from the oxygen source gas 562. The ozone gas is metered into the loadlock chamber 552 through an ozone supply valve 564 and an ozone supply line 565.

The loadlock apparatus 512 further includes a nitrogen source gas 566 which supplies nitrogen gas into the loadlock chamber 552 through a nitrogen supply valve 568 and a nitrogen supply line 569.

The loadlock apparatus 512 also includes a pump 558 which can be used to control the pressure within the loadlock chamber 552. A pressure detector 570 may also be included to monitor the pressure within the loadlock chamber 552.

There are advantages for forming the encapsulation oxide film in the loadlock apparatus 512. One advantage is that another chamber that is designated for a step in an existing process does not have to be dedicated for exposing the substrate to the ozone gas. Another advantage is that such a system is relatively safe because there is a substantially reduced likelihood that the ozone gas will mix with hydrogen gas within the cluster tool 500 and cause an explosion because the pressure within the loadlock apparatus 512 is always isolated from the area around the loadlock apparatus 512 when the ozone gas is within the loadlock apparatus 512 so that there is reduced likelihood that the ozone gas will escape to a surrounding area and cause an explosion. Another advantage is that the overall time taken to process wafers or substrates is maintained.

In one exemplary embodiment, the loadlock apparatus 512 is coupled to a controller 540. The controller 540 is similar to the controllers 2050 and 150 shown in FIGS. 3 and 4. The controller 540 is typically a computer having a processor (not shown) that can execute a program (a set of instructions) that controls all of the components of the cluster tool 500. The processor is similar to the processor 2054 and 154 shown in FIGS. 3 and 4.

In one embodiment, the controller 540 controls the operations of the chambers that are included in the cluster tool 500 (e.g., chambers 510, 509, 504, 506, 502, and 512). For example, the program receives an input from the pressure detector 570 and controls all of the components based on the pressure detected by the pressure detector 570. Additionally, the controller 540 controls the thinning of the substrate in the GCIB chamber 507, the smoothing of the silicon film surface in using the annealing process in the annealing chamber 509, and smoothing of the silicon film surface using the H₂:HCl etching process in the smoothing chamber 508. Additionally, the controller 540 controls the forming of the encapsulation film on the silicon film in the loadlock apparatus 512. The process controller for the cluster tool 500 may also control the making of the SOI substrate according to the exemplary embodiments described above.

FIGS. 6A-6K illustrate exemplary embodiments where an implant and cleave process is used to form an SOI substrate or wafer. In order to form an SOI substrate as illustrated in FIGS. 6A-6K, a handle wafer 600 and a donor wafer 650 as shown in FIG. 6A are provided. The donor wafer 650 is the wafer (or substrate) that provides a layer or layers to be transferred. The handle wafer 600 is the wafer or substrate that receives the transferred layers from the donor wafer 650 and is the wafer which eventually becomes the substrate for the SOI substrate.

The handle wafer 600 includes a monocrystalline silicon substrate 602. The silicon substrate 602 can be doped to any conductivity type (n-type or p-type) and to any conductivity level desired. In one exemplary embodiment, the silicon substrate 602 is a p-type substrate having a doping density of between 10¹⁵ -10¹⁹ atoms/cm³. The handle wafer 600 can also include an oxide film 604 formed thereon. In one exemplary embodiment the oxide film 604 is between 1000-5000 Å thick. The oxide film 604 can be thermally grown by exposing silicon substrate 602 to an oxidizing ambient, such as oxygen (O₂), at a temperature between 800-1250° C. in the oxide chamber 510.

The donor wafer 650 includes a monocrystalline silicon substrate 652 with an oxide film 654 formed thereon. The silicon substrate 650 can be doped to any desired conductivity type and level desired. In an embodiment of the present invention silicon substrate can be doped to a level between 10¹⁵-10¹⁹ atoms/cm³. The oxide film 654 can be formed by thermally oxidizing a layer of the silicon substrate 650 in an oxidizing ambient in the oxide chamber 510 as described above. The oxide film 654 typically has a thickness between 1000-5000 Å.

In another exemplary embodiment, only one of the donor wafer 650 or the handle wafer 600 has the oxide film grown thereon. Thus, only the oxide film 604 is grown on the handle wafer 600 or only the oxide film 654 is grown on the donor wafer 650.

Next, as shown is FIG. 6B, the donor wafer 650 is implanted with ions to form dislocation 656. To implant the ions, the donor wafer 650 is moved into the implant chamber 504. The donor wafer 650 can be implanted with hydrogen atoms or with inert ions such Argon (Ar) or Helium (He). In one exemplary embodiment, the donor wafer 650 is ion implanted with a plasma immersion ion implantation process. Such a process can implant high doses of H₂ gas into the monocrystalline silicon substrate 652 of the donor wafer 650. In such a process, a high voltage negative bias is applied to the donor wafer 650 to accelerate the ions towards the wafer face (the oxide film 654). The plasma immersion ion implantation process implants the entire donor wafer surface. In another exemplary embodiment, the P-III Ion Implantation System developed by Silicon Genesis can be used for a plasma immersion ion implantation step. Further yet, the ion implantation can be carried out using, for example, beam line ion implantation equipment manufactured from companies such as Applied Materials, Axcelis Corp., Varian, and others.

In one exemplary embodiment, the implantation of the hydrogen atoms generates an internal hydrogen rich layer 656 within the donor wafer 650. The depth, D, of the ion implantation peak determines the amount of silicon 658 which is subsequently removed from the silicon substrate 652 of the donor wafer 650. In one exemplary embodiment, the hydrogen ions are implanted between 1000-5000 Å into substrate 652 of donor wafer 650.

Next, the ion implanted donor wafer 650 and the handle wafer 600 are bonded together. The ion implanted donor wafer 650 and the handle wafer 600 are placed into the bond/cleave chamber 506. In the bond/cleave chamber 506, the donor wafer 650 is bonded to the handle wafer 600 as shown in FIG. 6D. In one exemplary embodiment, the oxide film 654 of the donor wafer 650 is bonded to the oxide film 604 of the handle wafer 600.

In one exemplary embodiment, the handle wafer 600 and the donor wafer 650 are bonded using a low temperature plasma activated bond process. By using plasma activation of the bond interface, higher bond strength can be achieved at low process temperatures (e.g. room temperature). In this embodiment, and as shown in FIG. 6C, both the handle wafer 600 and the donor wafer 650 are exposed to a low temperature plasma in order to generate plasma activated bonding surfaces 606 and 660 respectably. It is to be appreciated that other suitable bonding techniques may be used to bond the handle wafer to the donor wafer.

In the bonding process, in one exemplary embodiment, the donor wafer 650 is flipped upside down so that bond interface 660 can be attached to the bond interface 606 of handle wafer 600 as shown in FIG. 6D. The donor and handle wafer stack is then compressed together to securely bond the interface 660 and the interface 606 (indicated in FIG. 6C). The plasma activation of the bond interface helps achieve a sufficiently strong bonding for a subsequent room temperature cleaving process.

Next, as shown in FIG. 6E, the lower portion 659 of silicon substrate 652 of the donor wafer 650 is separated or cleaved from the upper portion of the silicon layer 658 at the dislocation 656 of the donor wafer 650. In one exemplary embodiment, a Room Temperature Controlled Cleaved Process (RT/CCP) is used to separate the bonded pair at the implant dislocation 656 without using heat. The RT/CCP process initiates a separation at one point on the wafer and propagates that separation cross the entire wafer through a mechanical cleaving method. In another exemplary embodiment and as shown in FIG. 6E, a nitrogen (N₂) stream is focused at the edge of the dislocation to cause the separation.

The implant, bond, and cleave process transfers the oxide film 654 and the silicon film 658 to the handle wafer 600. The transfer generates an SOI substrate, which comprises a silicon wafer 602 with an oxide layer 669 (the combination of the oxide films 654 and 604) buried under a thin layer 658 of monocrystalline silicon. The thickness of the top silicon layer 658 is determined by the depth of the hydrogen implant. In one exemplary embodiment, the top silicon film 658 requires further thinning to achieve a thickness, for example, a thickness less than 200 Å. The silicon film 658 also requires smoothing since the bonding and cleaving process leave the silicon film 658 with a rough surface as shown in FIG. 6E.

As mentioned and as shown in FIG. 6E, the implant and cleave process forms a very rough silicon surface 660, where silicon film 658 is separated from silicon substrate 652. More thinning is typically necessary to produce a thin or ultra-thin silicon film 658. In one embodiment, the desired final thickness of the silicon film 658 is less than 200 Å. The implant and cleave process typically forms a silicon surface having a surface roughness of between 20-80 Å RMS. In order to provide a suitable finish, the handle wafer 600 along with the oxide layer 669 and the silicon 658 is first transferred into the GCIB chamber for thinning.

FIG. 6F illustrates the SOI substrate with the rough silicon film 658 that needs to be thinned and smoothed. Before thinning the silicon film 658 the initial thickness the silicon film 658 is measured. The initial non-uniformity of the silicon film 658 is also characterized. The characterization of the initial thickness and non-uniformity can be done ex-situ to the GCIB chamber 507 or in-situ.

In one embodiment, the characterization of the initial thickness and non-uniformity is done ex-situ using reflectometry or other suitable conventional techniques. The initial thickness and the non-uniformity across the silicon film 658 allows for a determination of an initial non-uniformity profile of the silicon film 658. In one exemplary embodiment, a thickness measuring device such as the reflectometer is included in the cluster tool 500 as one of the process chamber. In one embodiment, the reflectometry technique is used to measure thickness across the silicon film 658. The initial mean thickness of the silicon film 658 is then calculated based on the thickness measurements across the silicon film 658. The reflectometry technique can produce a point-by-point film thickness map of the silicon film 658 that may be reduced to a thickness contour graph. An example of such a contour graph is illustrated in FIG. 7.

In FIG. 7, the plus signs on the contour graph indicate that the sites with the plus signs are above (or thicker than) the calculated mean thickness of the silicon film 658. The minus signs on the contour graph indicate that the sites with the minus signs are below (or thinner than) the calculated mean thickness of the silicon film 658. In one embodiment, the number of the sites of the silicon film 658 that are measured depends on the variation in thickness across the silicon film. For example, more sites can be measured if (1) the measurement is fast, and (2) the initial uniformity profile of the silicon film 658 has many features. The contour graph thus gives the initial non-uniformity mapping information of the silicon film 658. In another example, the characterization of the initial thickness and non-uniformity is done in-situ using a reflectometer or other suitable conventional techniques that are incorporated within the GCIB chamber 507.

The non-uniformity mapping information is stored as a series of thickness points with precise wafer positions into a memory by a controller. In one embodiment, an intended non-uniformity mapping information is created for an intended non-uniformity profile that is to be incorporated into the silicon film 658. In one embodiment, the intended non-uniformity mapping information is created by experimental determinations of an etching profile of an H₂:HCl etching process, which is subsequently used to smooth the silicon film 658. For example, as illustrated in FIG. 6G, an intended non-uniformity profile 671 is created for the silicon film 658. In one embodiment, the intended non-uniformity mapping information is stored as a series of thickness points with precise wafer positions into the memory by the controller.

In one embodiment, a mathematical algorithm is then employed which takes the initial non-uniformity mapping information and the intended non-uniformity mapping information to create a scanning program that has an etching pattern that is depended upon the initial non-uniformity profile and the intended non-uniformity profile. The scanning program thins the silicon film 658 and incorporates the intended non-uniformity profile into the surface of the silicon film 658 as illustrated in FIG. 6H.

In another embodiment, a mathematical algorithm is employed which takes the initial non-uniformity mapping information to create a scanning program that has an etching pattern that is depended upon the initial non-uniformity profile. The scanning program simply thins the silicon film 658 to a thickness.

Next, a smoothing process used to smooth the surface of the silicon film 658. In one embodiment, a H₂:HCl etching process is used. As illustrated in FIG. 61, the H₂:HCl etching process has an etching profile 673 which compensates the intended non-uniformity profile and hence, smoothes out the intended non-uniformity profile.

To smooth the silicon film 658 using the H₂:HCl etching process, the SOI substrate is placed in the smoothing chamber 508. Silicon film 658 can be suitably treated by heating the handle wafer 600 to a temperature between 1000° C.-1300° C., preferably between 1050° C.-1200° C., and then exposing the thinned silicon film 658 to a gas mixture comprising H₂ and HCl gases. In one exemplary embodiment, the handle wafer 600 is exposed to the gas mixture that comprises an H₂:HCl molecular concentration ratio between 10:1 and 1000:1. The handle wafer 600 is heated and exposed to the H₂ and HCl gas mixture until the silicon film 658 has a suitably smooth surface finish 664 is obtained as illustrated in FIG. 6J.

Additionally, the H₂:HCl concentration ratio can be varied during smoothing process in order to increase or decrease the removal rate. And, the H₂:HCl flow can be varied across the surface of the wafer (inner and outer locations) in order to manipulate the removal rate across the surface of the wafer.

In another exemplary embodiment, the annealing process is used to smooth the surface of the silicon film 658. In this embodiment, the SOI substrate (e.g., the handle wafer 602, the oxide layer 669, and the silicon film 658) is placed in the annealing chamber 509. The annealing chamber 509 can be a conventional rapid thermal annealing processing chamber well known in the art. In another example, the annealing chamber 509 can be a chamber similar to the apparatus 210 shown in FIG. 4. The SOI substrate is heated up to a soak temperature, (an annealing temperature), of about 1200° C. or higher. In one embodiment, a gas flow of a mixture including one or more gases such as H₂, N₂, He, Ar, or O₂ is introduced into the annealing chamber while the SOI substrate is being heated up. In one embodiment, the flow rate of the gas mixture can be greater than 1000 seem for an annealing chamber of a 5-7 liter size. In one embodiment, the gas flow is across the SOI substrate across the silicon film 658. In another example, an inert gas (e.g., Ar, Xe, He, or N₂) flow is introduced to the backside of the SOI substrate for fast cool down of the SOI substrate after annealing. In one embodiment, the SOI substrate is annealed in the presence of H₂ for about 10 seconds to 60 seconds.

In one embodiment, the silicon film 658 has a surface roughness less than 5 Å RMS and preferably less than 1 Å RMS after the smoothing process is completed. In one exemplary embodiment, about 1800 Å of the silicon film 658 can be removed to generate a sufficiently smooth surface. In another embodiment, the silicon film 658 thinned to less than 200 Å and preferably between 50-100 Å. Such a thin silicon film 658 can be used to produce a compliant substrate for depositing a relaxed defect free epitaxial silicon germanium film.

Next, if desired, an encapsulation film 666 is formed on the thinned and smoothened silicon film 658 as illustrated in FIG. 6K. In one embodiment, the encapsulation film 666 is a high quality silicon dioxide film formed using the loadlock apparatus 512 described above.

In another embodiment, additional silicon film(s) (not shown) can be formed on the thinned and smoothened silicon film 658. In one exemplary embodiment, the additional silicon film(s) are formed in the chamber 508 in which the silicon film 658 was smoothed. In this way, the treated silicon 658 is not exposed to an oxidizing ambient or to other potential contaminants prior to the formation of the additional silicon films. This process is particularly useful for forming a protecting silicon layer on the SOI substrate.

In one exemplary embodiment, the additional silicon film is a single crystalline silicon film (epitaxial silicon) that can be formed by a chemical vapor deposition process in the chamber 508 using a silicon source gas, such as trichlorosilane or silane, and H₂ gas. The additional silicon film can be formed to any thickness desired and can be formed to any conductivity type and density desired. In one embodiment, the silicon film 666 has a p-type conductivity type and a dopant density between 10¹⁵-10¹⁹ atoms/cm³ and is formed to a total thickness between 1000 Å-50,000 Å. Alternatively, the silicon film can be a silicon alloy such as silicon germanium.

A method and apparatus for treating a silicon or silicon alloy surface has been described. Although the present invention has been described with respect to the treatment of a silicon film of an SOI substrate, and more particularly to a silicon film of an SOI substrate formed by an implant and cleave process, the present invention is not to be limited to the exemplary embodiments. One skilled in the art will appreciate the ability to use the present invention to treat any silicon film and its surface to thin and smooth the silicon film. The silicon film treated using the exemplary embodiments has a uniform thickness across the silicon film, a smooth film surface across the silicon film, and a film thickness as thin as less than 200 Å.

1. A method of treating a silicon film comprising:
providing a silicon film;
treating said silicon film using a gas cluster ion beam (GCIB) process; and
annealing said silicon film using an annealing process to smooth at least one surface of said silicon film.

2. The method of claim 1 further comprising:
forming an encapsulation film over said silicon film to protect said silicon film after said thinning and said smoothing.

3. A method of treating a silicon film comprising:
mapping an initial non-uniformity profile on said silicon surface to obtain an initial non-uniformity mapping information;
directing a gas cluster ion beam (GCIB) toward said silicon surface while modulating said directing said GCIB according to said initial non-uniformity mapping information to thin said silicon film to a thickness; and
smoothing at least one surface of said silicon film using an annealing process.

4. The method of claim 3 further comprising:
forming an encapsulation film over said silicon film to protect said silicon film after said thinning and said smoothing.

5. The method of claim 4 wherein said annealing process occurs in a rapid thermal annealing chamber.

6. The method of claim 5 wherein said annealing process has a process temperature between 1100° C. and 1300° C. and said wherein said annealing process further comprises introducing a gas into said rapid thermal annealing processing chamber while heating up said silicon film.

7. The method of claim 5 wherein said silicon film is treated in said rapid thermal annealing chamber for about 10 seconds to 60 seconds.

8. A substrate processing system comprising:
a GCIB chamber having a first substrate holder to hold a substrate during a GCIB etching process, said substrate having a silicon film with a silicon surface that has an initial non-uniformity profile;
a rapid thermal annealing processing (RTP) chamber having a second substrate holder that holds said substrate during a smoothing process, said smoothing process anneals said silicon film in a presence of a gas;
a controller for controlling said GCIB chamber and said RTP chamber;
a machine-readable medium coupling to said controller, said machine-readable medium has a memory that stores a set of instructions for directing operations of said GCIB etching process and said smoothing process;
wherein said GCIB etching process thins said silicon film to a thickness and wherein said smoothing process smoothes out a surface of said silicon film after said silicon film is thinned with said GCIB etching process.

9. The method of claim 8 further comprising:
a loadlock apparatus wherein said controller is further for controlling said loadlock apparatus and wherein said set of instructions are further for forming an encapsulation film over said silicon film to protect said silicon film after said smoothing process.

10. The substrate processing system of claim 8 wherein said set of instructions are further for:
storing an initial non-uniformity mapping information for said initial non-uniformity profile of said silicon surface;
directing a gas cluster ion beam (GCIB) toward said silicon surface while modulating said directing said GCIB depending on said initial non-uniformity mapping information to thin said silicon film to said thickness; and
smoothing said silicon surface in said RTP chamber.

11. The substrate processing system of claim 8 wherein said set of instructions are further for maintaining a process temperature between 1100° C. and 1300° C. for said RTP chamber and instructions for introducing said gas into said RTP chamber while annealing said silicon film.

12. The substrate processing system of claim 8 wherein said set of instructions are further for annealing said silicon film in said RTP chamber for about 10 seconds to 60 seconds.

13. The substrate processing system of claim 8 wherein said gas is a mixture that includes one or more of an argon (Ar) gas, a xenon (Xe) gas, a hydrogen (H₂) gas, a nitrogen (N₂) gas, an oxygen (O₂) gas, or other gas.

14. A method of treating a silicon film comprising:
providing a silicon film;
incorporating an intended non-uniformity profile into a surface of said silicon film using a gas cluster ion beam (GCIB) process; and
smoothing said surface using an etching process having an etching profile that compensates for said intended non-uniformity profile.

15. The method of claim 14 further comprising:
forming an encapsulation film over said silicon film to protect said silicon film after said smoothing.

16. A method of treating a silicon film comprising:
providing a silicon film;
obtaining an initial mean thickness and initial non-uniformity profile for said silicon film;
thinning said silicon film to a thickness while incorporating an intended non-uniformity profile into a surface of said silicon film;
smoothing said surface using an etching process having an etching profile that compensates for said intended non-uniformity profile.

17. The method of claim 16 further comprising:
forming an encapsulation film over said silicon film to protect said silicon film after said smoothing.

18. A method of treating a silicon film comprising:
mapping an initial non-uniformity profile on said silicon surface to obtain an initial non-uniformity mapping information;
creating an intended non-uniformity mapping information for an intended non-uniformity profile to be incorporated into said silicon surface;
directing a gas cluster ion beam (GCIB) toward said silicon surface while modulating said directing said GCIB according to said initial non-uniformity mapping information and said intended non-uniformity mapping information to thin said silicon film to a thickness and to incorporate said intended non-uniformity profile into said silicon surface as said silicon film is being thinned; and
smoothing said silicon surface using an etching process having an etching profile that compensates for said intended non-uniformity profile.

19. The method of claim 18 further comprising:
forming an encapsulation film over said silicon film to protect said silicon film after said smoothing.

20. The method of claim 18 wherein said smoothing process is a H₂:HCl etching process.

21. The method of claim 20 wherein said H₂:HCl etching process occurs in a single wafer deposition chamber.

22. The method of claim 20 wherein said H₂:HCl etching process has a process temperature between 1000° C. and 1300° C. and wherein said H₂:HCl etching process further comprises exposing said silicon surface to a hydrochloric acid and hydrogen gas mixture.

23. The method of claim 20 wherein the said hydrochloric acid and hydrogen gas mixture has a molecular concentration ratio of HCl to H₂ of between 10:1 land 1000:1.

24. A substrate processing system comprising:
a GCIB chamber having a first substrate holder to hold a substrate during a GCIB etching process, said substrate having a silicon film with a silicon surface that has an initial non-uniformity profile;
a smoothing chamber having a second substrate holder to hold said substrate during a smoothing process;
a controller for controlling said GCIB chamber and said smoothing chamber;
a machine-readable medium coupling to said controller, said machine-readable medium has a memory that stores a set of instructions for directing operations of said GCIB etching process and said smoothing process;
wherein said GCIB etching process thins said silicon film and incorporates an intended non-uniformity profile into said silicon film and wherein said smoothing process has an smoothing profile that compensates for said intended non-uniformity profile.

25. The method of claim 24 wherein said smoothing process is a H₂:HCl etching process.

26. The method of claim 24 further comprising:
a loadlock apparatus wherein said controller is further for controlling said loadlock apparatus and wherein said set of instructions are further for forming an encapsulation film over said silicon film to protect said silicon film after said smoothing process.

27. The substrate processing system of claim 24 wherein said set of instructions are further for:
storing an initial non-uniformity mapping information for said initial non-uniformity profile of said silicon surface;
storing an intended non-uniformity mapping information for said intended non-uniformity profile;
directing a gas cluster ion beam (GCIB) toward said silicon surface while modulating said directing said GCIB depending on said initial non-uniformity mapping information and said intended non-uniformity mapping information to thin said silicon film to a thickness and to incorporate said intended non-uniformity profile into said silicon surface as said silicon film is being thinned; and
smoothing said silicon surface in said smoothing chamber.

28. The substrate processing system of claim 25 wherein said set of instructions are further for operating said smoothing process at a process temperature between 1000° C. and 1300° C.

29. The substrate processing system of claim 25 wherein said set of instructions are further for introducing a hydrochloric acid and hydrogen gas mixture into said smoothing chamber with a molecular concentration ratio of HCl to H₂ of between 10:1 to 1000:1 during said smoothing process.

30. A method of treating a silicon film comprising:
providing a silicon film;
treating said silicon film using a gas cluster ion beam (GCIB) process; and
treating said silicon film using an H₂:HCl etching process to smooth at least one surface of said silicon film.

31. The method of claim 30 wherein said treating said silicon film using said GCIB process further comprises incorporating an intended non-uniformity profile into a surface of said silicon film and wherein said treating said silicon film using said H₂:HCl etching process smoothes out said intended non-uniformity profile.

32. The method of claim 31 further comprising:
forming an encapsulation film over said silicon film to protect said silicon film after said treating said silicon film using said H₂:HCl etching process.

33. A method of treating a silicon film comprising:
providing a silicon film;
treating said silicon film to thin said silicon film and to incorporate an intended-non-uniformity profile into said silicon film; and
smoothing said silicon film to smooth out said intended non-uniformity profile.

34. The method of claim 33 further comprising:
incorporation said intended non-uniformity using a GCIB etching process.

35. The method of claim 34 further comprising:
smoothing out said intended non-uniformity using H₂:HCl etching process.

36. The method of claim 33 further comprising:
forming an encapsulation film over said silicon film to protect said silicon film after said treating said silicon film using said H₂:HCl etching process.
